(19) United States
(12) Patent Application Publication
(10) Pub. No.: US 2026/0173915 A1
(43) Pub. Date: Jun. 18, 2026

(54) POWER MODULE

(71) Applicant: Advanced Semiconductor Engineering, Inc., Kaohsiung (TW)

(72) Inventors: Yu-Chang CHEN, Kaohsiung (TW); Wei-Chun LEE, Kaohsiung (TW)

(73) Assignee: Advanced Semiconductor Engineering, Inc., Kaohsiung (TW)

(21) Appl. No.: 18/983,267

(22) Filed: Dec. 16, 2024

(51) Int. Cl. H01L 23/538; H01L 23/00; H01L 23/31; H01L 23/498; H01L 25/16; H05K 1/14; H05K 1/18

(52) U.S. Cl. CPC H10W 70/614; H10W 70/611; H10W 70/658; H10W 90/00; H10W 90/401; H05K 1/147; H05K 1/181; H10W 72/252; H10W 72/327; H10W 72/352; H10W 72/877; H10W 74/114; H10W 90/724; H10W 90/734

(57) ABSTRACT

The present disclosure provides a power module. The power module includes a first circuit structure, a second circuit structure, and a first power element. The second circuit structure is over the first circuit structure. The first power element is disposed between the first circuit structure and the second circuit structure. The first power element is configured to transmit a power passing through the first power element and the first circuit structure.

### BACKGROUND

### 1. Technical Field

The present disclosure relates to a power module.

### 2. Description of the Related Art

In a comparative power module, a low-side switch element and a high-side switch element are arranged on a single circuit structure, connected by conductive wires, resulting in a relatively large dimension. To address this and resolve other issues, such as thermal dissipation, a new power module is needed to reduce the overall size and enhance performance.

### SUMMARY

In some arrangements, a power module includes a first circuit structure, a second circuit structure, and a first power element. The second circuit structure is over the first circuit structure. The first power element is disposed between the first circuit structure and the second circuit structure. The first power element is configured to transmit a power passing through the first power element and the first circuit structure.

In some arrangements, a power module includes a first circuit structure, a second circuit structure, a first power element, and a second power element. The second circuit structure is over the first circuit structure. The first power element is disposed between the first circuit structure and the second circuit structure. The second power element is disposed between the first circuit structure and the second circuit structure. The first power element and the second power element are connected in series with each other to define a half-bridge circuit.

In some arrangements, a power module includes a first circuit structure, a second circuit structure, a first power element, and a driving element. The second circuit structure is over the first circuit structure. The first power element is disposed between the first circuit structure and the second circuit structure. The driving circuit is configured to switch the first power element. An input signal passes through the second circuit structure, and an output signal passes through the first circuit structure.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1A illustrates a top view of a power module in accordance with some arrangements of the present disclosure.

FIG. 1B illustrates a cross-sectional view along line A-A′ of the power module as shown in FIG. 1A in accordance with some arrangements of the present disclosure.

FIG. 1C illustrates an electrical path of the power module as shown in FIG. 1B in accordance with some arrangements of the present disclosure.

FIG. 2 illustrates a cross-sectional view of a power module in accordance with some arrangements of the present disclosure.

FIG. 3 illustrates a cross-sectional view of a power module in accordance with some arrangements of the present disclosure.

FIG. 4 illustrates a cross-sectional view of a power module in accordance with some arrangements of the present disclosure.

FIG. 5 illustrates a cross-sectional view of a power module in accordance with some arrangements of the present disclosure.

FIG. 6 illustrates a cross-sectional view of a power module in accordance with some arrangements of the present disclosure.

FIG. 7 illustrates a circuit of a power module in accordance with some arrangements of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

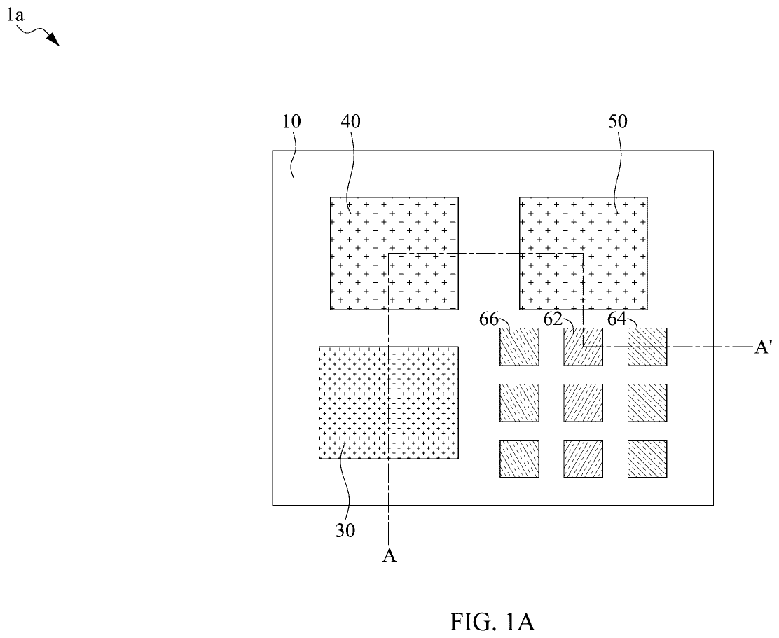

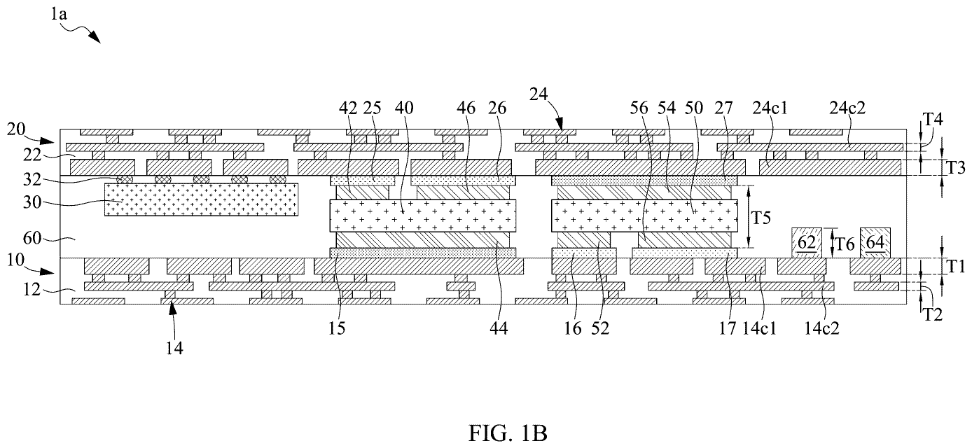

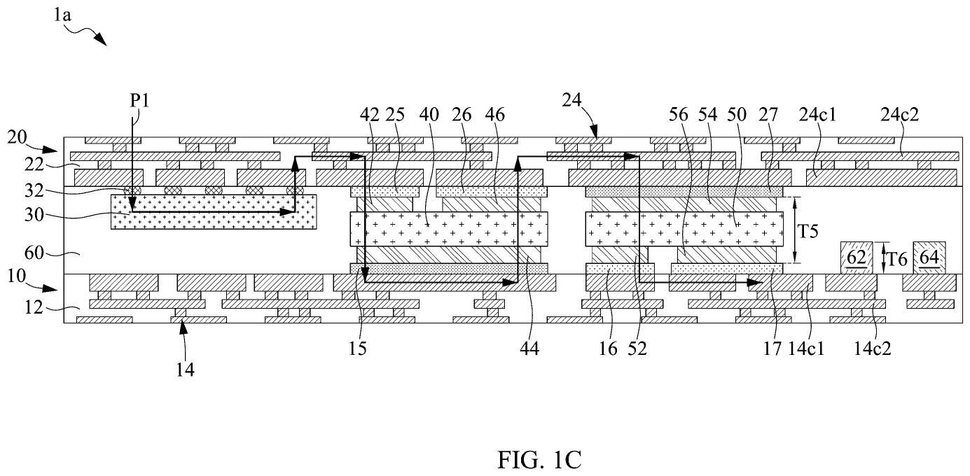

FIG. 1A illustrates a top view of a power module 1a, and FIG. 1B illustrates a cross-sectional view along line A-A′ of FIG. 1A in accordance with some arrangements of the present disclosure. It should be noted that some features are omitted from FIG. 1A for brevity.

In some arrangements, the power module 1a may be configured to modulate the power and be connected to other devices. In some arrangements, the power module 1a may be configured to function as a power inverter that converts at least one direct current (DC) signal to an alternating current (AC) signal. In some arrangements, the power module 1a may form a part of a power electronics circuit for use in various power applications such as in a DC/AC inverter, a DC/DC converter, an AC/DC converter, a DC/AC converter, an AC/AC converter, a multi-phase inverter, an H-bridge, etc. The power module 1a may include a half-bridge arrangement having a high-side switch element and a low-side switch element. In some arrangements, the high-side switch element and the low-side switch element are connected in series with each other to define a half-bridge circuit.

FIG. 1A illustrates the layout of the power module 1a from a top view, and the power module 1a may include a circuit structure 10, a driving element 30, a power element 40, a power element 50, passive devices 62, passive devices 64, and passive devices 66.

Referring to FIG. 1B, the circuit structure 10 (or lower circuit structure) may be configured to be electrically connected to the driving element 30. The circuit structure 10 may be configured to support the power element 40. The circuit structure 10 may be configured to be electrically connected to the power element 40. The circuit structure 10 may be configured to support the driving element 30. The circuit structure 10 may be configured to support the power element 50. The circuit structure 10 may be configured to be electrically connected to the power element 50. The circuit structure 10 may be configured to support the passive devices 62 and/or passive devices 64. The circuit structure 10 may be configured to be electrically connected to the passive devices 62 and/or passive devices 64. Although not shown in FIG. 1B, the passive devices 66 may be supported by the circuit structure 10 and electrically connected to the circuit structure 10.

In some arrangements, the circuit structure 10 may be a flexible substrate or a rigid substrate, depending upon the applications according to various embodiments. In some arrangements, the circuit structure 10 may include a printed circuit board or a flexible printed circuit board, such as a paper-based copper foil laminate, a composite copper foil laminate, or a polymer-impregnated glass-fiber-based copper foil laminate. The circuit structure 10 may include a redistribution layer (RDL) or traces, for electrical connection between components. The circuit structure 10 may include a dielectric structure 12 and a redistribution structure 14 embedded within the dielectric structure 12. The dielectric structure 12 may include polyimide, polypropylene, polybenzoxazole, benzocyclobuten, or other suitable materials. The redistribution structure 14 may be embedded within the dielectric structure 12. The redistribution structure 14 may include a plurality of conductive traces extending horizontally (or laterally) and conductive vias extending vertically and connecting conductive traces at different levels (or elevations).

In some arrangements, the redistribution structure 14 may include conductive traces with different dimensions (e.g., thickness and/or width). For example, the redistribution structure 14 may include a conductive trace 14c1 with a thickness T1 and a conductive trace 14c2 with a thickness T2 different from the thickness T1. In some arrangements, the conductive trace 14c1 is closer to the upper surface, which faces the power element 40, of the circuit structure 10 than the conductive trace 14c2 is. For example, the conductive trace 14c1 is closer to the power element 40 (or power element 50) than the conductive trace 14c2 is. In some arrangements, the thickness T1 may be equal to or greater than 20 μm, such as 20 μm, 25 μm, 30 μm, 35 μm, 40 μm, or greater. In some arrangements, the thickness T2 may be equal to or less than 15 μm, such as 15 μm, 12 μm, 10 μm, 8 μm, 5 μm, or less. In other embodiments, the conductive trace 14c2 may have a thickness substantially the same as the thickness T1 of the conductive trace 14c1. When the conductive traces of the redistribution structure 14 have larger dimensions (e.g., thickness and/or width), the power module 1a may experience higher current or voltage levels. Additionally, the thermal transmissivity may be improved.

In some arrangements, the power module 1a may further include a circuit structure 20 (or upper circuit structure). In some arrangements, the circuit structure 20 may be configured to support the driving element 30. In some arrangements, the circuit structure 20 may be configured to be electrically connected to the driving element 30. In some arrangements, the circuit structure 20 may be configured to be electrically connected to the power element 40. In some arrangements, the circuit structure 20 may be configured to be electrically connected to the power element 50. The circuit structure 20 may be configured to be electrically connected to the passive devices 62, passive devices 64, and/or passive devices 66 (shown in FIG. 1A).

In some arrangements, the circuit structure 20 may be a flexible substrate or a rigid substrate, depending upon the applications according to various embodiments. In some arrangements, the circuit structure 20 may include a printed circuit board or a flexible printed circuit board, such as a paper-based copper foil laminate, a composite copper foil laminate, or a polymer-impregnated glass-fiber-based copper foil laminate. The circuit structure 20 may include a redistribution layer or traces, for electrical connection between components. The circuit structure 20 may include a dielectric structure 22 and a redistribution structure 24 embedded within the dielectric structure 22. The dielectric structure 22 may include polyimide, polypropylene, polybenzoxazole, benzocyclobuten, or other suitable materials. The redistribution structure 24 may be embedded within the dielectric structure 22. The redistribution structure 24 may include a plurality of conductive traces extending horizontally (or laterally) and conductive vias extending vertically and connecting conductive traces at different levels (or elevations).

In some arrangements, the redistribution structure 24 may include conductive traces with different dimensions (e.g., thickness and/or width). For example, the redistribution structure 24 may include a conductive trace 24c1 with a thickness T3 and a conductive trace 24c2 with a thickness T4 different from the thickness T3. In some arrangements, the conductive trace 24c1 is closer to the lower surface, which faces the power element 40, of the circuit structure 20 than the conductive trace 24c2 is. For example, the conductive trace 24c1 may be closer to the power element 40 (or power element 50) than the conductive trace 24c2 is. In some arrangements, the thickness T1 may be equal to or greater than 20 μm, such as 20 μm, 25 μm, 30 μm, 35 μm, 40 μm, or greater. In some arrangements, the thickness T2 may be equal to or less than 15 μm, such as 15 μm, 12 μm, 10 μm, 8 μm, 5 μm, or less. In other embodiments, the conductive trace 24c2 may have a thickness substantially the same as the thickness T3. When the conductive traces of the redistribution structure 24 have larger dimensions (e.g., thickness and/or width), the power module 1a may experience higher current or voltage levels. Additionally, the thermal transmissivity may be improved.

In some arrangements, the driving element 30 may be disposed on or attached to the lower surface of the circuit structure 20. The driving element 30 may be disposed between the circuit structure 10 and the circuit structure 20. The driving element 30 may be configured to receive an input signal and switch (e.g., turn on or turn off) the power element 40. The driving element 30 may be directly coupled to the gate of the power element 40. The driving element 30 may be configured to receive an input signal and switch the power element 50. The driving element 30 may be directly coupled to the gate of the power element 50. The driving element 30 may include a semiconductor die which includes one or more driving circuits configured to switch the power element 40 and/or 50.

In some arrangements, the driving element 30 may be attached to the circuit structure 20 through electrical connectors 32. The electrical connectors 32 may include a reflowable material. The electrical connectors 32 may include a solder material(s), which may include alloys of gold and tin solder or alloys of silver and tin solder, or other suitable materials.

In some arrangements, the power elements 40 and 50 may be electrically connected to each other and define at least a portion of a half-bridge circuit. For example, the power element 40 may have a first gate, a first terminal, and a second terminal. The power element 50 may have a second gate, a third terminal, and a fourth terminal. The first gate may be configured to receive an input signal. The first terminal may be configured to receive a first power supply (e.g., a positive voltage), and the fourth terminal may be configured to receive a second power supply (e.g., a negative voltage). The second gate may be configured to receive an input signal. The second terminal may be directly coupled to the third terminal. A node between the second terminal and the third terminal may be coupled to an output node of the power elements 40 and 50.

In some arrangements, the power element 40 may be disposed between the circuit structure 10 and circuit structure 20. In some arrangements, the power element 40 may be or include a transistor. The power element 40 may function as a part of a high-side switch element, which may be coupled between a positive voltage supply and an output node. In some arrangements, the dimension (e.g., volume, thickness, and the like) of the power element 40 may be greater than that of the driving element 30.

The power element 40 may include a gate electrode 42, a source/drain (S/D) electrode 44, and an S/D electrode 46. The gate electrode 42 (or gate) may be attached to or abut the circuit structure 20. The S/D electrode 44 (or terminal) may be attached to or abut the circuit structure 10. The S/D electrode 46 (or terminal) may be attached to or abut the circuit structure 20. In some arrangements, the S/D electrode 44 may function as a drain of the power element 40. In some arrangements, the S/D electrode 46 may function as a source of the power element 40. In some arrangements, the S/D electrode 44 may have a surface area greater than that of the gate electrode 42. In some arrangements, the S/D electrode 44 may have a surface area greater than that of the S/D electrode 46.

In some arrangements, the S/D electrode 44 may be coupled to the circuit structure 10 by an electrical connector 15. The electrical connector 15 may have a surface area greater than that of the S/D electrode 44. In some arrangements, the gate electrode 42 may be coupled to the circuit structure 20 by an electrical connector 25. The electrical connector 25 may have a surface area greater than that of the gate electrode 42. In some arrangements, the S/D electrode 46 may be coupled to the circuit structure 20 by an electrical connector 26. The electrical connector 26 may have a surface area greater than that of the S/D electrode 46. The electrical connector 15, electrical connector 25, and electrical connector 26 may include a reflowable material. The electrical connector 15, electrical connector 25, and electrical connector 26 may include a solder material(s), which may include alloys of gold and tin solder or alloys of silver and tin solder, or other suitable materials. For example, the reflowable temperature of the electrical connector 15, electrical connector 25, and electrical connector 26 may be about 260 degrees Celsius or higher.

In some arrangements, the power element 50 may be disposed between the circuit structure 10 and circuit structure 20. In some arrangements, the power element 50 may be or include a transistor. The power element 50 may function as a part of a low-side switch element, which may be coupled between a negative voltage supply and an output node. In some arrangements, the dimension (e.g., volume, thickness, and the like) of the power element 50 may be greater than that of the driving element 30.

In some arrangements, the power element 50 may include a gate electrode 52, and S/D electrodes 54 and 56. The gate electrode 52 (or gate) may be attached to or abut the circuit structure 10. In some arrangements, the S/D electrode 54 (or terminal) may be attached to or abut the circuit structure 20. In some arrangements, the S/D electrode 56 (or terminal) may be attached to or abut the circuit structure 10. In some arrangements, the S/D electrode 54 may function as a drain of the power element 50. In some arrangements, the S/D electrode 56 may function as a source of the power element 50. In some arrangements, the S/D electrode 54 may have a surface area greater than that of the gate electrode 52. In some arrangements, the S/D electrode 54 may have a surface area greater than that of the S/D electrode 56.

In some arrangements, the gate electrode 52 may be coupled to the circuit structure 10 by an electrical connector 16. The electrical connector 16 may have a surface area greater than that of the gate electrode 52. In some arrangements, the S/D electrode 56 may be coupled to the circuit structure 10 by an electrical connector 17. The electrical connector 17 may have a surface area greater than that of the S/D electrode 56. In some arrangements, the S/D electrode 54 may be coupled to the circuit structure 20 by an electrical connector 27. The electrical connector 27 may have a surface area greater than that of the S/D electrode 54. The electrical connectors 16, 17, and 27 may include a reflowable material. The electrical connectors 16, 17, and 27 may include a solder material(s), which may include alloys of gold and tin solder or alloys of silver and tin solder, or other suitable materials.

In some arrangements, the gate electrode 42 of the power element 40 may be free from laterally overlapping the gate electrode 52 of the power element 50. For example, the gate electrode 42 is attached to the circuit structure 20, and the gate electrode 52 is attached to the circuit structure 10. In some arrangements, the S/D electrode 44 of the power element 40 may be free from laterally overlapping the S/D electrode 54 of the power element 50. For example, the S/D electrode 44 is attached to the circuit structure 10, and the S/D electrode 54 is attached to the circuit structure 20.

In some arrangements, the power package 1a may include an encapsulant 60. The encapsulant 60 may be disposed between the circuit structure 10 and circuit structure 20. In some arrangements, the encapsulant 60 may encapsulate the driving element 30. In some arrangements, the encapsulant 60 may encapsulate the power element 40. In some arrangements, the encapsulant 60 may encapsulate the power element 50. The encapsulant 60 may include a molding compound. The encapsulant 60 may include a novolac-based resin, an epoxy-based resin, a silicone-based resin, or another suitable material. Suitable fillers may also be included, such as powdered SiO₂. The encapsulant 60 may be applied using any of a number of molding techniques, such as compression molding, injection molding, or transfer molding. In other embodiments, the encapsulant 60 may include, for example, organic materials (e.g., a bismaleimide triazine (BT), a polyimide (PI), a polybenzoxazole (PBO), a solder resist, an ABF, a polypropylene (PP) or an epoxy-based material), inorganic materials (e.g., a silicon, a glass, a ceramic or a quartz), liquid and/or dry-film materials or a combination thereof.

In some arrangements, the passive devices 62 may be attached to or abut the circuit structure 10 as well as disposed between the circuit structure 10 and circuit structure 20. The passive devices 62 may be encapsulated by the encapsulant 60. In some arrangements, the passive devices 64 may be attached to or abut the circuit structure 10 as well as disposed between the circuit structure 10 and circuit structure 20. The passive devices 64 may be encapsulated by the encapsulant 60. Although not shown in FIG. 1B, it should be noted that the passive devices 66 may be encapsulated by the encapsulant 60. The passive devices 62, passive devices 64, and passive devices 66 may define an RLC circuit. For example, the passive devices 62 may include inductors, the passive devices 64 may include capacitors, and the passive devices 66 may include resistors. The power element 40 (or power element 50) may have a thickness T5, which may be defined as a distance from the lower surface of the drain and an upper surface of the source. The passive devices 64 may have a thickness T6. In some arrangements, the thickness T5 may be greater than the thickness T4. The passive devices 62 may laterally overlap the S/D electrode 44. The passive devices 62 may laterally overlap the S/D electrode 56. The passive devices 62 may laterally overlap the gate electrode 52.

FIG. 1C illustrates an electrical path P1 of the power module 1a. In some arrangements, the electrical path P1, which indicates the transmission path of power (or power signal), may pass through the driving element 30 through the circuit structure 20. The electrical path P1 may pass through the power element 40 from the driving element 30 through the circuit structure 20. The electrical path P1 may pass through the circuit structure 10 from the circuit structure 20 through the power element 40. The electrical path P1 may pass through the power element 50 from the power element 40 through the circuit structure 20. The electrical path P1 may pass through the circuit structure 10 from the circuit structure 20 through the power element 50. It should be noted that the electrical path P1 provided is merely an example. The signal or current of power module 1a may vary depending on the on or off condition of power elements 40 and 50.

In a comparative example, the low-side switch element and the high-side switch element are disposed on a single circuit structure, with some of the electrodes of the low-side switch element and the high-side switch element being electrically connected to the circuit structure by conductive wires (e.g., wire bonds). This setup requires additional space to accommodate the conductive wires and only allows heat to be transmitted by one side. In another comparative example, heat sink structures are placed on two opposite sides of a comparative power module. In this scenario, signals can only be transmitted laterally through, for example, lead frames, necessitating additional space to accommodate them. The arrangements of this disclosure use an additional circuit structure and eliminate the need for spaces for conductive wires. Additionally, two circuit structures can be configured to transmit heat and power, thereby enhancing the performance of the power module and its thermal transmissivity.

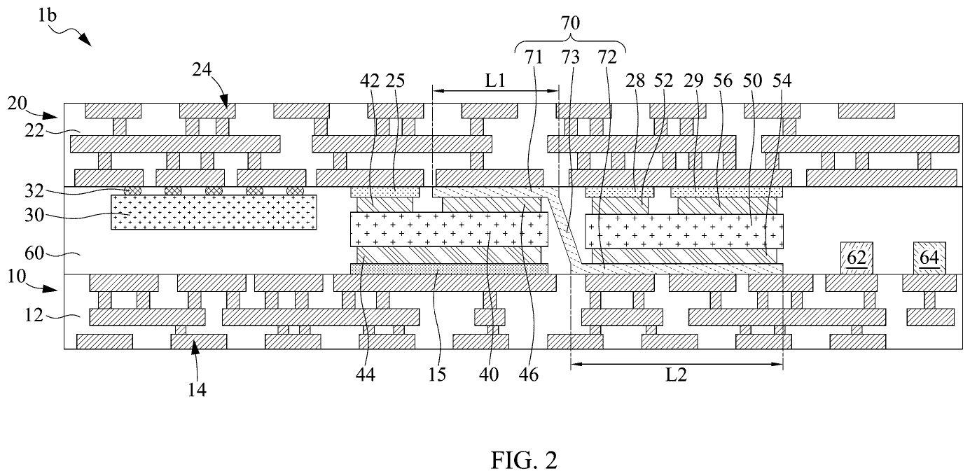

FIG. 2 illustrates a cross-sectional view of a power module 1b in accordance with some arrangements of the present disclosure. The power module 1b is similar to the power module 1a in FIG. 1B except for the differences described as follows.

In some arrangements, the gate electrode 52 may be attached to or abut the circuit structure 20. The S/D electrode 54 may be attached to or abut the circuit structure 10. The S/D electrode 56 may be attached to or abut the circuit structure 20. In some arrangements, the gate electrodes 42 and 52 may be arranged at the same side of the power module 1b. In some arrangements, the gate electrode 42 may laterally overlap the gate electrode 52.

In some arrangements, the gate electrode 52 may be coupled to the circuit structure 20 by an electrical connector 28. The electrical connector 28 may have a surface area greater than that of the gate electrode 52. In some arrangements, the S/D electrode 56 may be coupled to the circuit structure 20 by an electrical connector 29. The electrical connector 29 may have a surface area greater than that of the S/D electrode 56. The electrical connectors 28 and 29 may include a reflowable material. The electrical connectors 28 and 29 may include a solder material(s), which may include alloys of gold and tin solder or alloys of silver and tin solder, or other suitable materials.

In some arrangements, the power module 1b may further include a conductive feature 70. The conductive feature 70 may be configured to electrically connect the power elements 40 and 50. In some arrangements, the conductive feature 70 may be disposed between the circuit structure 10 and circuit structure 20. In some arrangements, the conductive feature 70 may penetrate the encapsulant 60. In some arrangements, the conductive feature 70 may include a conductive material, such as copper, aluminum, gold, silver, titanium, alloy, or other suitable materials.

In some arrangements, the conductive feature 70 may be configured to connect one of the source/drain electrodes of the power element 40 to another one of the source/drain electrodes of the power element 50. For example, the conductive feature 70 may be configured to connect the S/D electrode 46 (e.g., source electrode) of the power element 40 and the S/D electrode 54 (e.g., drain electrode) of the power element 50.

The conductive feature 70 may have portions 71, 72, and 73. The portion 71 may be disposed between the S/D electrode 46 and the circuit structure 20. The portion 72 may be disposed between the circuit structure 10 and the S/D electrode 54. The portion 73 may connect the portions 71 and 72. In some arrangements, the portion 73 may be slanted with respect to the portion 71. In some arrangements, the portion 73 may be slanted with respect to the portion 72. In some arrangements, the portion 73 may be slanted with respect to the upper surface of the circuit structure 10. In some embodiments, a length L1 of the portion 71 may be less than a length L2 of the portion 72. Since the electrodes having substantially the same dimension of the power elements 40 and 50 are located at the same side, the process of mounting these elements to the circuit structure 10 can be simplified. This enhancement in the manufacturing process leads to a reduction in cycle time.

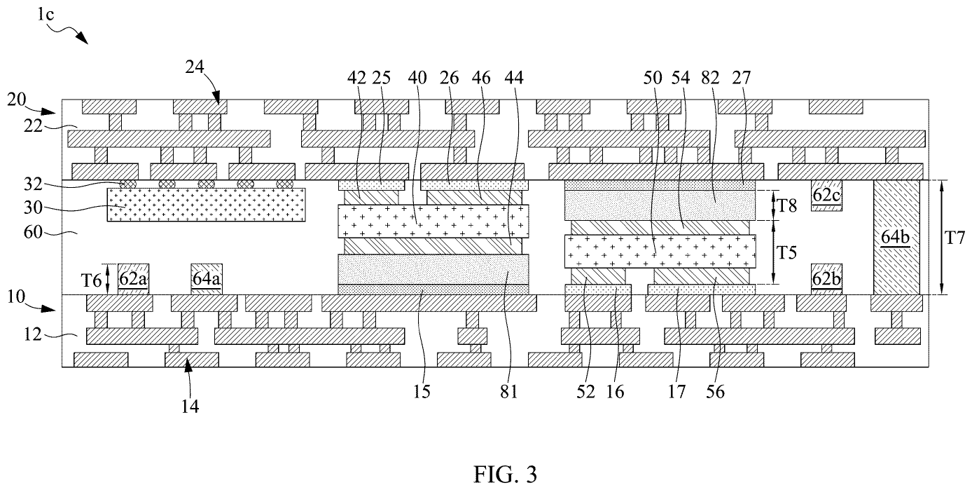

FIG. 3 illustrates a cross-sectional view of a power module 1c in accordance with some arrangements of the present disclosure. The power module 1c is similar to the power module 1a in FIG. 1B except for the differences described as follows.

In some arrangements, the power module 1c may include spacers 81 and 82. In some arrangements, each of the spacers 81 and 82 may be configured to adjust the distance between the circuit structure 10 and circuit structure 20 or adjust the thickness of the encapsulant 60. In some arrangements, each of the spacers 81 and 82 may include a conductive material, such as copper, aluminum, gold, silver, titanium, alloy, or other suitable materials. In some arrangements, the spacers 81 and 82 may include conductive pastes, which may be cured after heated. The spacer 81 may be disposed between the S/D electrode 44 of the power element 40 and the circuit structure 10. In some arrangements, the spacer 81 may have a surface area greater than that of the S/D electrode 44. The spacer 82 may be disposed between the S/D electrode 54 of the power element 40 and the circuit structure 20. In some arrangements, the spacer 82 may have a surface area greater than that of the S/D electrode 54.

In some arrangements, the passive devices 62a and 62b may be disposed on or attached to the circuit structure 10, and the passive device 62c may be disposed on or attached to the circuit structure 20. In some arrangements, the passive device 64a may be disposed on or attached to the circuit structure 10, and the passive device 64b may be connected between the circuit structure 10 and circuit structure 20. In some arrangements, the passive device 62a may be disposed under the driving element 30. In some arrangements, the passive device 62a may vertically overlap the driving element 30. In some arrangements, the passive device 62b may vertically overlap the passive device 62c.

The passive device 64b may have a thickness T7. The thickness T7 of the passive device 64b may be greater than the thickness T6 of the passive device 64a. In some arrangements, the thickness T7 of the passive device 64b may be greater than the thickness T5 of the power element 40 (or power element 50). The spacer 81 (or spacer 82) may have a thickness T8. In some arrangements, the thickness T7 may be substantially equal to or slightly greater than the sum of the thickness T5 and the thickness T8.

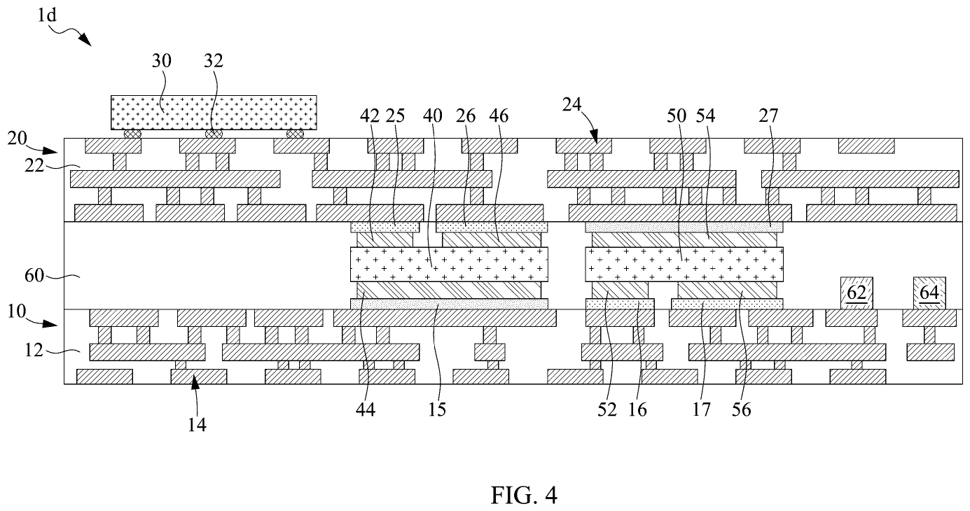

FIG. 4 illustrates a cross-sectional view of a power module 1d in accordance with some arrangements of the present disclosure. The power module 1d is similar to the power module 1a in FIG. 1B except for the differences described as follows.

In some arrangements, the driving element 30 may be disposed on or over the circuit structure 20. In some arrangements, the driving element 30 may be free from laterally overlapping the power element 40. In some arrangements, the driving element 30 may be free from laterally overlapping the power element 50.

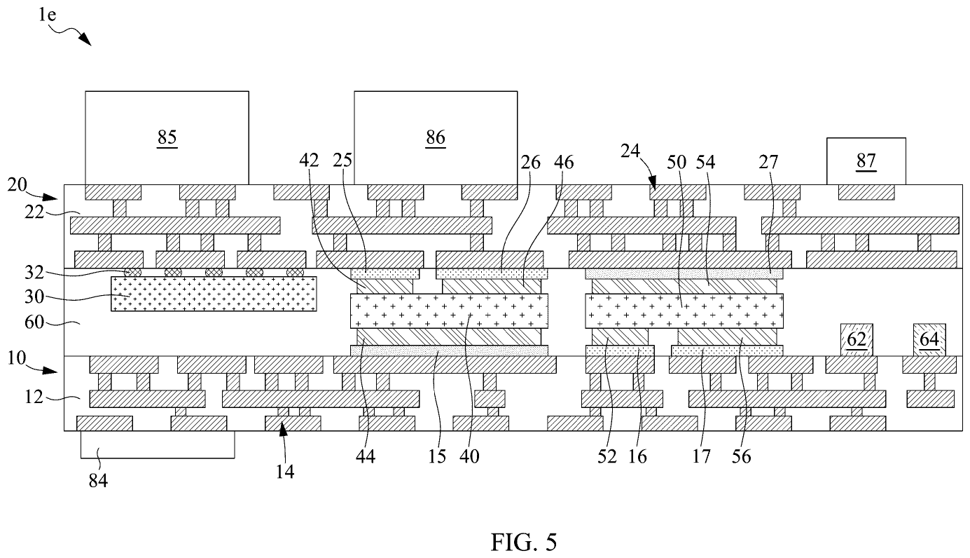

FIG. 5 illustrates a cross-sectional view of a power module 1e in accordance with some arrangements of the present disclosure. The power module 1e is similar to the power module 1a in FIG. 1B except for the differences described as follows.

In some arrangements, the power module 1e may include electronic components 84, 85, 86, and 87. In some arrangements, the electronic components 84, 85, 86, and 87 may be electrically connected to the power element 40 and/or 50 through the circuit structure 10 and/or 20. In some arrangements, the electronic component 84 may be disposed on or under the circuit structure 10. In some arrangements, the electronic components 85, 86, and 87 may be disposed on or over the circuit structure 20. In some arrangements, the electronic components 85, 86, and 87 may have different thicknesses. In some arrangements, each of the electronic components 84, 85, 86, and 87 may include an active device or a passive device. The active device may include a semiconductor die or a chip, such as a logic die (e.g., application processor (AP), system-on-a-chip (SoC), central processing unit (CPU), graphics processing unit (GPU), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies) or other active devices. In some embodiments, the electronic components 84, 85, 86, and 87 may include a plurality of transistors, diodes, or other elements. The transistor may include a bipolar junction transistor, metal-oxide-semiconductor field-effect transistor (MOSFET), junction gate field-effect transistor (JFET) and other transistors. The diode may include a Zener diode, photodiode, Schottky diode and other diodes. The passive device may include a capacitor, inductor, resistor, or other suitable passive devices.

In some arrangements, the electronic components 85, 86, and 87 may include inductors and/or capacitors. In some arrangements, the electronic components 84 may include an active device, such as a die.

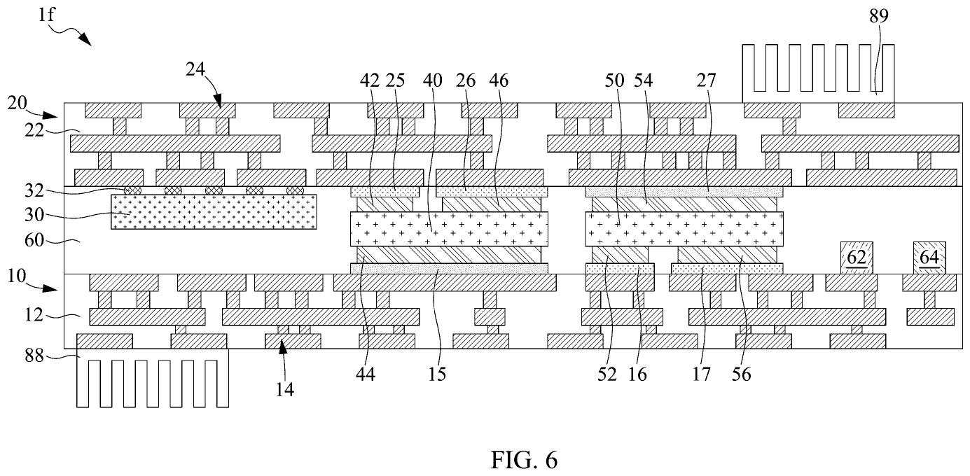

FIG. 6 illustrates a cross-sectional view of a power module 1f in accordance with some arrangements of the present disclosure. The power module 1f is similar to the power module 1a in FIG. 1B except for the differences described as follows.

In some arrangements, the power module 1f may include heat dissipating structures 88 and 89. In some arrangements, the heat dissipating structure 88 may be disposed on or under the circuit structure 10. In some arrangements, the heat dissipating structure 89 may be disposed on or over the circuit structure 20. Each of the heat dissipating structures 88 and 89 may be configured to enhance the thermal transmissivity.

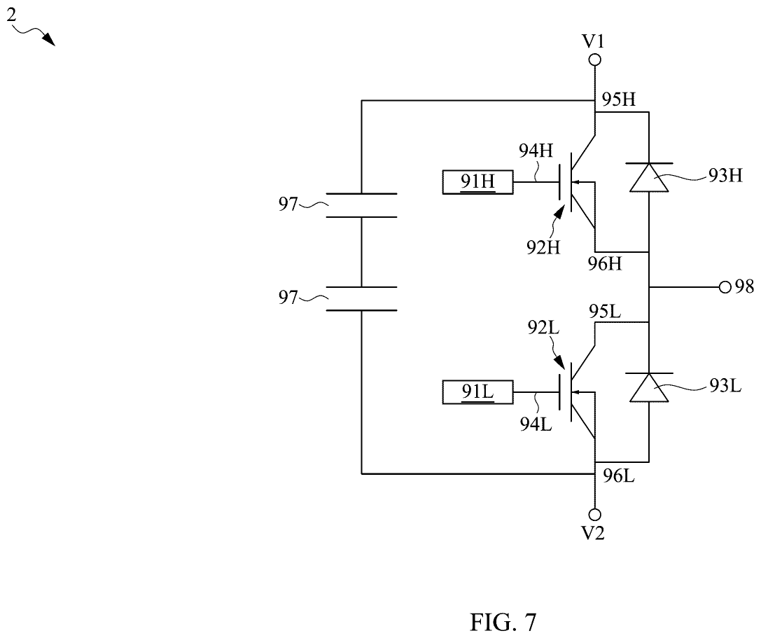

FIG. 7 illustrates a circuit 2 of a power module in accordance with some arrangements of the present disclosure.

In some arrangements, the circuit 2 may include a high-side driver 91H, a low-side driver 91L, a high-side transistor 92H, a low-side transistor 92L, a high-side diode 93H, and a low-side diode 93L. The high-side transistor 92H and the high-side diode 93H may define a high-side switch element. The low-side transistor 92L and the low-side diode 93L may define a low-side switch element. The high-side switch element may be electrically connected to the low-side switch element in series and define a half-bridge circuit. The high-side transistor 92H may include a terminal 94H, terminal 95H, and terminal 96H. The high-side driver 91H may be coupled to the terminal 94H and turn on or off the high-side transistor 92H. The low-side transistor 92L may include a terminal 94L, terminal 95L, and terminal 96L.

The high-side driver 91H may be configured to receive an input terminal. The high-side driver 91H may be coupled to the terminal 94H and turn on or off the high-side transistor 92H. Under the control of the high-side driver 91H, the high-side switch element switches, between a conducting state and a non-conducting state, the path between the terminal 95H and terminal 96H. The terminal 95H may be coupled to a supply voltage V1 (e.g., a positive voltage). The anode and the cathode of the high-side diode 93H are connected to the terminal 95H and the terminal 96H, respectively, of the high-side transistor 92H.

The low-side driver 91L may be configured to receive an input terminal. The low-side driver 91L may be coupled to the terminal 94L and turn on or off the low-side transistor 92L. Under the control of the low-side driver 91L, the high-side switch element switches, between a conducting state and a non-conducting state, the path between the terminal 95L and terminal 96L. The terminal 96L may be coupled to a supply voltage V2 (e.g., a negative voltage). The anode and the cathode of the low-side diode 93L are connected to the terminal 95L and the terminal 96L, respectively, of the low-side transistor 92L.

The terminal 95H may be coupled to capacitor 97. The terminal 96L may be coupled to the capacitor 97. The terminal 96H may be coupled to the terminal 95L. Each of the terminal 96H and terminal 95H may be coupled to an output node 98.

In some arrangements, the driving element 30 as shown in FIG. 1B may function as the high-side driver 91H and/or low-side driver 91L. In some arrangements, the power element 40 as shown in FIG. 1B may function as the high-side transistor 92H. In some arrangements, the power element 50 as shown in FIG. 1B may function as the low-side transistor 92L.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A power module, comprising:
a first circuit structure;
a second circuit structure over the first circuit structure; and
a first power element disposed between the first circuit structure and the second circuit structure,
wherein the first power element is configured to transmit a power passing through the first power element and the first circuit structure.

2. The power module of claim 1, further comprising:
a passive element disposed on the first circuit structure,
wherein a thickness of the passive element is less than a thickness of the first power element.

3. The power module of claim 1, further comprising:
a passive element configured to support the first circuit structure and the second circuit structure,
wherein a thickness of the passive element is greater than a thickness of the first power element.

4. The power module of claim 1, wherein the first circuit structure comprises a first conductive trace at a first level and a second conductive trace at a second level different from the first level, and a thickness of the first conductive trace is greater than a thickness of the second conductive trace.

5. The power module of claim 4, wherein the first conductive trace is closer to the first power element than the second conductive trace is.

6. The power module of claim 1, further comprising:
a driving element; and
a second power element disposed between the first circuit structure and the second circuit structure, wherein the driving element is configured to switch the second power element.

7. The power module of claim 6, wherein the first power element comprises a first gate electrode attached to the second circuit structure, and the second power element comprises a second gate electrode attached to the first circuit structure.

8. The power module of claim 6, wherein the first power element comprises a first gate electrode attached to the second circuit structure, and the second power element comprises a second gate electrode attached to the second circuit structure.

9. The power module of claim 8, further comprising:
a conductive feature electrically connecting the first power element and the second power element, wherein the conductive feature is disposed between the first circuit structure and the second circuit structure.

10. The power module of claim 9, wherein the conductive feature is configured to electrically connect a first source/drain electrode of the first power element and a second source/drain electrode of the second power element.

11. The power module of claim 10, wherein the conductive feature has a portion slanted with respect to a surface of the first circuit structure.

12. The power module of claim 11, further comprising:
a passive element laterally overlapping the portion of the conductive feature.

13. A power module, comprising:
a first circuit structure;
a second circuit structure over the first circuit structure;
a first power element disposed between the first circuit structure and the second circuit structure; and
a second power element disposed between the first circuit structure and the second circuit structure,
wherein the first power element and the second power element are connected in series with each other to define a half-bridge circuit.

14. The power module of claim 13, further comprising:
a passive element electrically connected to the first power element and disposed between the first circuit structure and the second circuit structure,
wherein the passive element laterally overlaps terminals of the first power element.

15. The power module of claim 13, further comprising:
an encapsulant encapsulating the first power element and the second power element; and
a conductive feature configured to electrically connect a first source/drain electrode of the first power element and a second source/drain electrode of the second power element, wherein the conductive feature penetrates the encapsulant.

16. The power module of claim 13, wherein the first power element comprises a first gate electrode abutting the second circuit structure, a first source/drain electrode abutting the second circuit structure, and a second source/drain electrode abutting the first circuit structure, and a surface area of the second source/drain electrode is greater than that of the first source/drain electrode.

17. The power module of claim 16, wherein the second power element comprises a second gate electrode abutting the first circuit structure.

18. A power module, comprising:
a first circuit structure;
a second circuit structure over the first circuit structure;
a first power element disposed between the first circuit structure and the second circuit structure; and
a driving element configured to switch the first power element,
wherein the driving element and the first power element are configured to provide an electrical path passing through the first circuit structure and the second circuit structure.

19. The power module of claim 18, further comprising:
a second power element electrically connected to the first power element in series, wherein a first gate electrode of the first power element abuts the second circuit structure, and a second gate electrode of the second power element abuts the first circuit structure.

20. The power module of claim 18, further comprising:
a first passive element and a second passive element between the first circuit structure and the second circuit structure, wherein the first passive element has a first thickness, and the second passive element has a second thickness different from the first thickness.
